(19) United States
(12) Patent Application Publication
(10) Pub. No.: US 2011/0090664 A1
(43) Pub. Date: Apr. 21, 2011

(54) SHIELD CASE MOUNTING SUBSTRATE

(76) Inventors: Yukihiro Sumida, Osaka (JP); Toshiteru Nakawaki, Osaka (JP)

(21) Appl. No.: 12/995,696

(22) PCT Filed: Apr. 28, 2009
(86) PCT No.: PCT/JP2009/058330

§ 371 Date: Dec. 2, 2010

(30) Foreign Application Priority Data
Jun. 3, 2008 (JP) 2008-146049

(51) Int. Cl. H05K 9/00

(52) U.S. Cl. 361/818

(57) ABSTRACT

In a shield case mounting substrate, a downwardly extending portion of a shield case is solder-bonded to a first land pattern and a second land pattern which are provided on the surface of a substrate. The width of the first land pattern in the thickness direction of the downwardly extending portion is greater than the width of the second land pattern in the thickness direction of the downwardly extending portion. Consequently, the high bonding strength between the shield case and the substrate can be ensured, and the positioning accuracy of the shield case on the substrate can also be ensured.

### TECHNICAL FIELD

The present invention relates to a shield case mounting substrate on which a metal case for shielding is mounted.

### BACKGROUND ART

For electronic equipment such as a liquid crystal display device, a circuit substrate is used on which a plurality of electronic components (a resistance, a capacitor, a diode, a coil, a transmitter, and the like) are mounted for driving the equipment. Such a circuit substrate is generally configured to have a shield structure by which the electronic components are covered therearound with a metal case in order to block electrical noises generated from the mounted electronic components themselves and noises coming from the outside into the electronic components.

Generally, the shield structure is configured such that a part of the metal case is connected to a ground terminal provided on the circuit substrate. In particular, frequently used is a structure in which a protrusion formed on the metal case is soldered to a connection terminal formed on the substrate, to thereby cause the metal case to be grounded to the ground terminal.

In recent years, in accordance with a reduction in size of the electronic equipment, there is an increasing need to reduce the size of the circuit substrate disposed around the equipment and the size of the components mounted thereon. In addition, there is also an increasing need to reduce the size of the area on which the electronic components are mounted, the size of the metal case itself for covering the area and the size of the bonding area thereof. In the case of the conventional connection structure of the metal case, however, it is difficult to reduce the size of the bonding area in response to the needs.

Patent Document 1 (Japanese Patent Laying-Open No. 2006-344812) and Patent Document 2 (Japanese Patent Laying-Open No. 2003-309397) each disclose the mounting structure for a shielding metal case, for solving the above-described problems.

In Patent Document 1, as shown in FIG. 19, a metal case 1012 is provided at each corner section with a plate-shaped leg 1014 which extends obliquely with respect to two sides between which the corner section is interposed. On the side of a substrate 1011 corresponding to leg 1014, a land pattern 1015 having a triangular shape is formed, to which the lower end of leg 1014 is electrically connected along its oblique side.

Furthermore, in the structure disclosed in Patent Document 1, a fitting portion 1011a formed on the substrate 1011 side and a protrusion 1018 formed in metal case 1012 are fit into each other for positioning.

Furthermore, in the structure disclosed in Patent Document 2, as shown in FIGS. 20 and 21, a ground pad 2026 is provided at both ends of a printed circuit substrate 2025. A metal cap 2029 attached to printed circuit substrate 2025 has a configuration in which both edges of the flat plate are bent to form legs 2020. Ground pad 2026 and metal cap 2029 are solder-connected to each other. Metal cap 2029 is fixedly bonded by applying an adhesive 2028 on the upper surface of an electronic component 2003 which is the tallest of the components mounted on printed circuit substrate 2025.

### Prior Art Documents

### Patent Documents

### Patent Document 1: Japanese Patent Laying-open No. 2006-344812

### Patent Document 2: Japanese Patent Laying-open No. 2003-309397

### SUMMARY OF THE INVENTION

### Problems to be Solved by the Invention

In the structure disclosed in Patent Document 1, legs 1014 of metal case 1012 are solder-bonded to four land patterns 1015 provided on substrate 1011. Each land pattern 1015 on the circuit substrate is formed larger than the lower end of each leg 1014 of metal case 1012. Accordingly, when leg 1014 is mounted by solder reflow, the lower end of leg 1014 formed in metal case 1012 moves within land pattern 1015, which causes a problem that the position of the metal case is displaced. In order to solve this problem, it is proposed to reduce the size of land pattern 1015. This, however, also causes a problem that the solder bonding strength is decreased to cause metal case 1012 to be stripped off.

Furthermore, Patent Document 1 discloses the configuration in which, in order to prevent positional displacement, a notch portion 1011a is provided in a part of substrate 1011 and fit into protrusion 1018a formed on metal case 1012 to thereby prevent positional displacement. However, when a thin substrate such as a flexible printed circuit substrate is used as a substrate, the rigidity of the substrate itself is low. Consequently, metal case 1012 cannot be fixed even if a fitting portion is provided.

Furthermore, when the fitting portion is increased in size for maintaining a sufficient strength, there is also a problem of preventing space savings.

Patent Document 2 discloses a configuration in which printed circuit substrate 2025 is solder-bonded at its both ends and an adhesive 2028 is applied on the upper surface of the tallest of electronic components 2003 mounted on printed circuit substrate 2025, thereby fixedly adhering metal cap 2029. In the above-described configuration, the electronic component and the metal case are mounted by different bonding methods, and thus, in completely different processes, which causes a problem of an increase in cost. Furthermore, if an adhesion process is eliminated, the connection between leg 2020 of metal cap 2029 and ground pad 2026 is maintained only by solder bonding, which also causes a problem that the bonding strength cannot be sufficiently ensured.

The present invention has been made to solve the above-described problems and aims to provide a shield case mounting substrate that allows the bonding strength between the metal case and the substrate to be ensured and also allows the metal case to be positioned with high accuracy.

### Means for Solving the Problems

According to the present invention, a shield case mounting substrate includes a substrate; an electronic component mounted on the substrate; a shield case made of metal having a main body covering the electronic component from above and a downwardly extending portion contiguous to an end of the main body and extending downwardly in a direction of the substrate; a first land pattern provided on a surface of the substrate and to which a lower end of the corresponding downwardly extending portion is solder-bonded; and a second land pattern provided on the surface of the substrate and to which a lower end of the corresponding downwardly extending portion is solder-bonded. A width of the first land pattern in a thickness direction of the downwardly extending portion is greater than a width of the second land pattern in the thickness direction of the downwardly extending portion.

Preferably, the above-described shield case mounting substrate is configured such that, when a thickness of the downwardly extending portion is L1 and the width of the second land pattern in the thickness direction of the downwardly extending portion is L2, L1 and L2 are set so as to satisfy a relation of 1<(L2/L1)≦5.

Preferably, in the above-described shield case mounting substrate, a plurality of the first land patterns and a plurality of the second land patterns are provided.

Preferably, in the above-described shield case mounting substrate, an outer edge of the main body has four sides extending linearly, the downwardly extending portion is formed to extend downwardly from an edge of each of the four sides, at least four second land patterns are provided, and at least one of the second land patterns is provided in a position corresponding to each of the four sides.

Preferably, in the above-described shield case mounting substrate, the downwardly extending portion corresponding to the second land pattern has the lower end provided with a notch portion.

Preferably, in the above-described shield case mounting substrate, the substrate is a flexible printed circuit substrate.

### EFFECTS OF THE INVENTION

According to the shield case mounting substrate in accordance with the present invention, the bonding strength between the metal case and the substrate can be ensured, and the metal case can be positioned with high accuracy.

### BRIEF DESCRIPTION OF THE DRAWINGS

FIG. 1 is a perspective view showing the structure of a shield case in the first embodiment according to the present invention.

FIG. 2 is a perspective view showing the structure of a circuit substrate used in the first embodiment according to the present invention.

FIG. 3 is a perspective view showing the structure of a shield case mounting substrate in the first embodiment according to the present invention.

FIG. 4 is a plan view showing the positional relationship between the circuit substrate and the shield case in the first embodiment according to the present invention.

FIG. 5 is a cross-sectional view taken along a line V-V in FIG. 4 showing the bonding structure between the circuit substrate and the shield case in the first embodiment according to the present invention.

FIG. 6 is a cross-sectional view taken along a line VI-VI in FIG. 4 showing the bonding structure between the circuit substrate and the shield case in the first embodiment according to the present invention.

FIG. 7 is an enlarged view of a section A in FIG. 6 showing the bonding structure between the circuit substrate and the shield case in the first embodiment according to the present invention.

FIG. 8 is a perspective view showing the process of fixing the shield case to the circuit substrate according to the first embodiment.

FIG. 9 is a perspective view showing the process of fixing the shield case to the circuit substrate according to the first embodiment.

FIG. 10 is a perspective view showing the process of fixing the shield case to the circuit substrate according to the first embodiment.

FIG. 11 is a perspective view showing the process of fixing the shield case to the circuit substrate according to the first embodiment.

FIG. 12 is a perspective view showing the process of fixing the shield case to the circuit substrate according to the first embodiment.

FIG. 13 is a perspective view showing the structure of the shield case in the second embodiment according to the present invention.

FIG. 14 is an enlarged view of a section B in FIG. 13 showing the structure of the shield case in the second embodiment according to the present invention.

FIG. 15 is a perspective view showing the structure of the circuit substrate used in the second embodiment according to the present invention.

FIG. 16 is a perspective view showing the structure of the shield case mounting substrate of the second embodiment according to the present invention.

FIG. 17 is an enlarged cross-sectional view showing the structure of the connection portion of the shield case mounted on the circuit substrate in the second embodiment according to the present invention.

FIG. 18 is an enlarged cross-sectional view showing the structure of the connection portion of the shield case mounted on the circuit substrate in the second embodiment according to the present invention.

FIG. 19 is a perspective view showing the structure of the conventional shield case mounting substrate.

FIG. 20 is an exploded perspective view showing the structure of the conventional shield case mounting substrate.

FIG. 21 is a longitudinal cross-sectional view showing the structure of the conventional shield case mounting substrate.

### MODES FOR CARRYING OUT THE INVENTION

The structure of the shield case mounting substrate in each of the embodiments according to the present invention will be hereinafter described with reference to the accompanying drawings, in which the same or corresponding components in each embodiment are designated by the same reference characters, and description thereof will not be repeated.

### First Embodiment

A shield case mounting substrate 100 according to the present embodiment includes a circuit substrate 200; an electronic component 230b mounted on circuit substrate 200; a shield case 170 having a main body 172 covering electronic component 230b from above and a downwardly extending portion 180 contiguous to the end of main body 172 and extending downwardly in the direction of circuit substrate 200; a first land pattern 210 provided on the surface of circuit substrate 200 and to which the lower end of corresponding downwardly extending portion 180 is solder-bonded; and a second land pattern 220 provided on the surface of circuit substrate 200 and to which the lower end of corresponding downwardly extending portion 180 is solder-bonded.

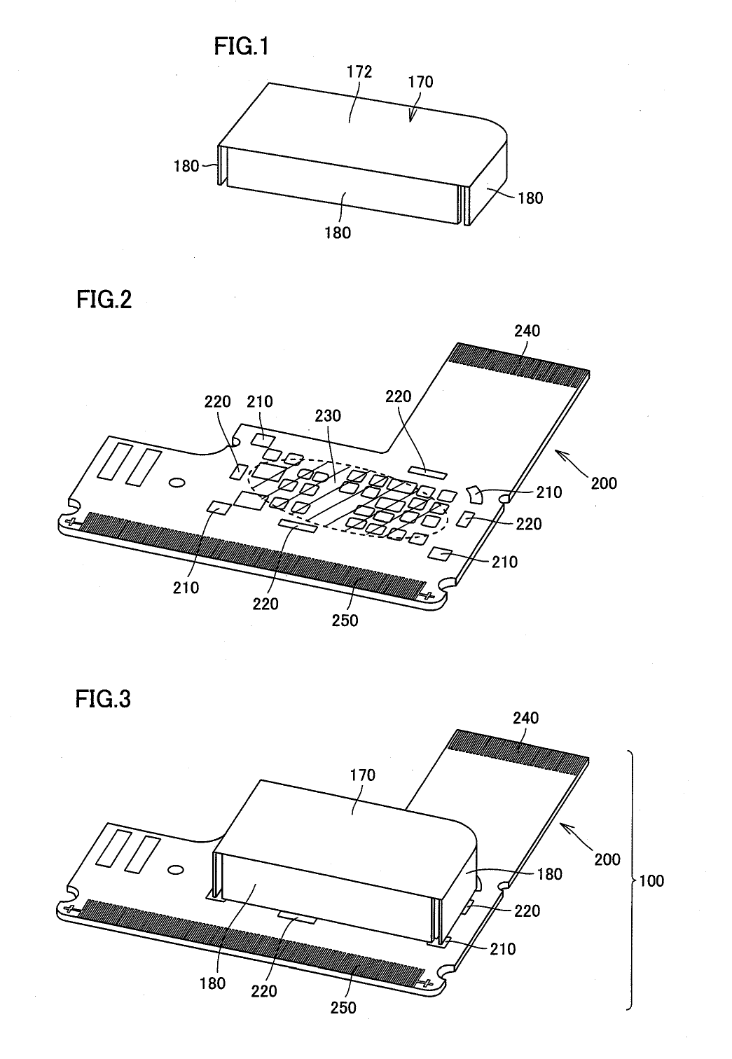

FIG. 1 is a perspective view showing the structure of a shield case in the present embodiment. In the present embodiment, shield case 170 is formed by bending a metal material. Shield case 170 has plate-shaped main body 172 covering the electronic component from above and plate-shaped downwardly extending portion 180 covering the lateral side of the electronic component.

The outer edge of main body 172 has four sides extending linearly and has an approximately rectangular shape in plan view. One of the corners of main body 172 is rounded. Main body 172 has an edge from which downwardly extending portion 180 contiguously extends in the state where it bends at a right angle with respect to main body 172. In this case, downwardly extending portion 180 extends at a right angle with respect to main body 172, but may not necessarily be at a right angle.

Shield case 170 according to the present embodiment is fabricated by bending four sides of the metal material by mold pressing. By way of example only, the thickness of the metal material used in the present embodiment is 0.1 mm.

FIG. 2 is a perspective view showing the structure of the circuit substrate used in the present embodiment. In the present embodiment, a flexible printed circuit substrate is used as circuit substrate 200. On circuit substrate 200, various wiring patterns, land patterns of an electronic component mounting area 230, and land patterns 210 and 220 used for mounting shield case 170 are formed by the well-known photolithography process.

Specifically, circuit substrate 200 is provided thereon with electronic component mounting area 230 on which electronic components such as a capacitor, a resistance, a coil, and a diode (electronic components are not shown) are mounted. Electronic component mounting area 230 is provided with a land pattern used for mounting the electronic components.

Furthermore, circuit substrate 200 is provided with land patterns 210 and 220 used for mounting shield case 170. Shield case 170 blocks the noise generated from electronic component mounting area 230 and the noise coming from the outside into electronic component mounting area 230.

Circuit substrate 200 is provided with an electronic equipment connection terminal 240 for transmitting a control signal from the electronic equipment main body (not shown) and a liquid crystal display element connection terminal 250 for supplying the control signal received from the electronic equipment main body to the liquid crystal display element (not shown).

FIG. 3 is a perspective view showing the structure of the shield case mounting substrate according to the present embodiment.

As shown in FIG. 3, in the present embodiment, the lower ends of downwardly extending portion 180 of shield case 170 are located on their respective land patterns 210 and 220. In the present embodiment, downwardly extending portion 180 of shield case 170 abuts on circuit substrate 200 approximately at a right angle. It is to be noted that the angle at which downwardly extending portion 180 abuts on circuit substrate 200 may not necessarily be a right angle. Shield case 170 and circuit substrate 200 are connected by soldering to each other. The specific connection process will be described later.

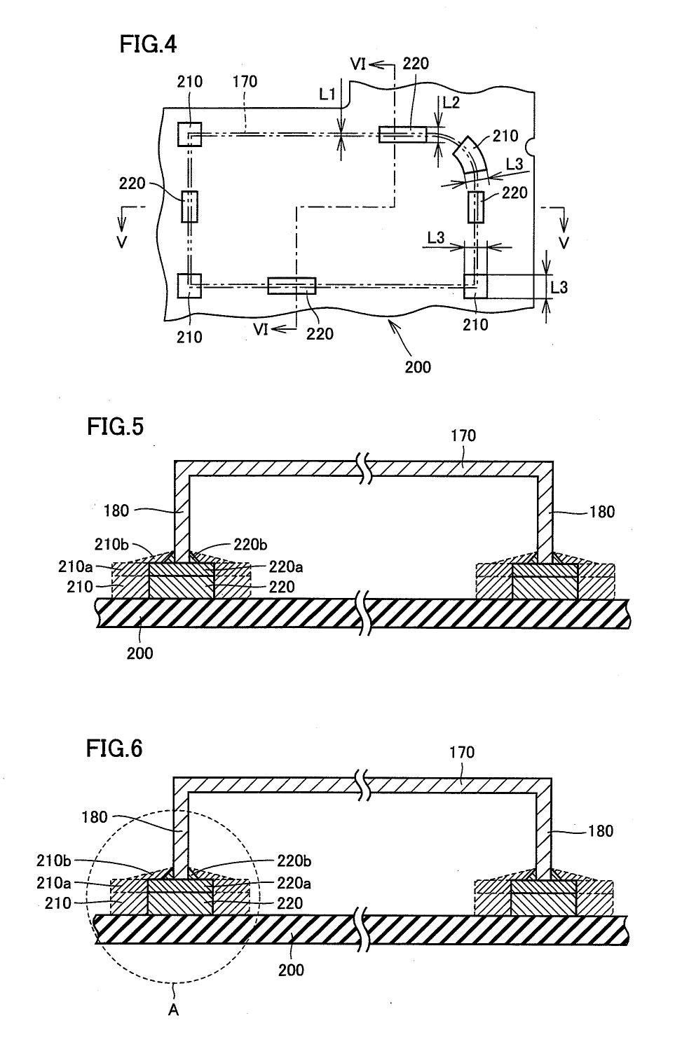

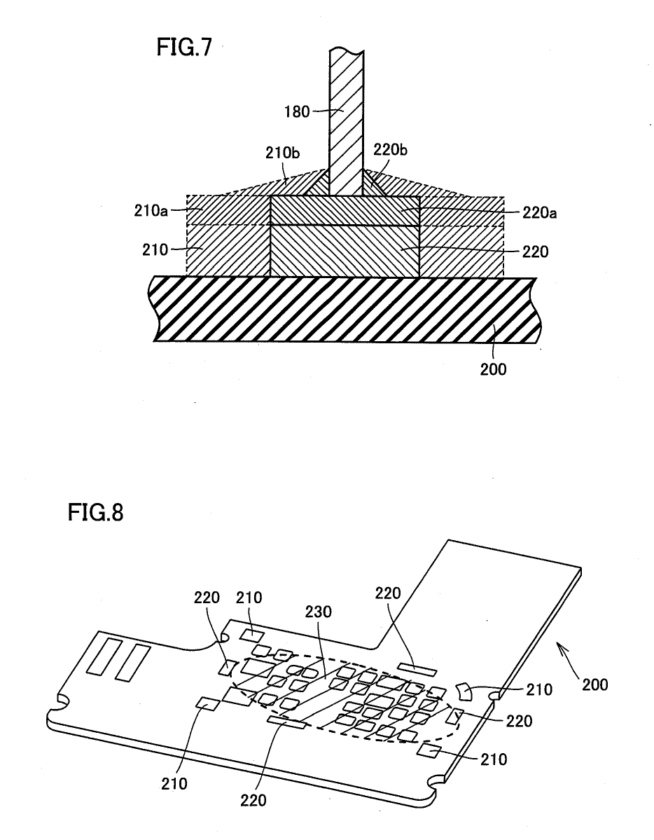

FIG. 4 is a plan view showing the positional relationship between the circuit substrate and the shield case in the present embodiment. FIG. 5 is a cross-sectional view taken along a line V-V in FIG. 4. FIG. 6 is a cross-sectional view taken along a line VI-VI in FIG. 4. FIG. 7 is an enlarged view of a section A in FIG. 6.

As shown in FIG. 4, land pattern 210 is provided in the position corresponding to each of four corner sections of shield case 170. This land pattern 210 serves as a land pattern for fixing shield case 170 (fixing land pattern). In the present embodiment, three of four fixing land patterns 210 are formed in the shape of a square.

Specifically, land pattern 210 is formed in the shape of a square having a side length of 0.75 mm and configured to have a sufficient thickness relative to the thickness (0.1 mm) of downwardly extending portion 180. It is preferable that fixing land pattern 210 is configured to have a sufficient width in the thickness direction of downwardly extending portion 180 in consideration of the thickness of downwardly extending portion 180. Accordingly, the area of contact between the solder and land pattern 210 can be ensured, thereby allowing the peel strength of the solder to be sufficiently ensured.

Land pattern 210 located in the curved corner section (located in the upper right area in FIG. 4) is curved along the shape of downwardly extending portion 180 of shield case 170. It is to be noted that the side that is not curved (the side orthogonal to downwardly extending portion 180) is equal in length to the side of land pattern 210 having a square shape.

Land pattern 220 serves as a land pattern for limiting the movable range of shield case 170 (positioning land pattern) in the process of fixing shield case 170 by solder reflow. Therefore, positioning land pattern 220 is configured to have a width L2 in the thickness direction of downwardly extending portion 180 that is less than a width L3 of fixing land pattern 210 in the thickness direction of downwardly extending portion 180.

By way of example only, in the present embodiment, positioning land pattern 220 is formed in the shape of a rectangle having a longer side of 1.0 mm and a shorter side of 0.5 mm. Four land patterns 220 are provided in total, each of which is disposed in a position on the corresponding one of four sides of shield case 170.

During solder reflow, downwardly extending portion 180 of shield case 170 moves within land pattern 220. Since positioning land pattern 220 has a shorter side having a length L2 of 0.5 mm and downwardly extending portion 180 has a thickness L1 of 0.1 mm, shield case 170 can be solder-bonded with positional accuracy of ±0.2 mm in the vertical and lateral directions.

In the present embodiment, downwardly extending portion 180 of shield case 170 is configured to have thickness L1 of 0.1 mm, and land pattern 220 is configured to have width L2 of 0.5 mm in the thickness direction of downwardly extending portion 180, with the result that the length ratio (L2/L1) is equal to 5. Land pattern 220 is thus formed to allow the positioning accuracy of shield case 170 to be ensured. In addition, the area on the substrate required for mounting shield case 170 can be reduced.

Also, since shield case 170 is provided on its corner section with fixing land pattern 210 that is greater in width than land pattern 220, the bonding strength by soldering can be sufficiently ensured. Since fixing land pattern 210 is separately provided for ensuring the bonding strength by soldering, positioning land pattern 220 can be further reduced in size. This leads to a further reduction in the area of the movable range of the lower end of downwardly extending portion 180 of shield case 170, with the result that the positioning accuracy of shield case 170 can be still further improved.

Downwardly extending portion 180 and land patterns 210 and 220 are solder-bonded to each other in the manner as shown in FIG. 7. Solder pastes 210a and 220a are formed on fixing land pattern 210 and positioning land pattern 220, respectively. The lower end of downwardly extending portion 180 is located on solder pastes 210a and 220a, which is then subjected to a reflow process. Consequently, solder pastes 210a and 220a are melted on the side of downwardly extending portion 180, thereby forming fillets 210b and 220b.

In the present embodiment, the solder bonding strength between downwardly extending portion 180 and positioning land pattern 220 is 0.48 kgf for each part. On the other hand, the solder bonding strength between downwardly extending portion 180 and fixing land pattern 210 is 0.54 kgf for each part. In this case, as described above, positioning land pattern 220 has a longer side having a length of 1.0 mm and fixing land pattern 210 has a side having a length of 0.75 mm. Although fixing land pattern 210 is shorter in side length than positioning land pattern 220, fixing land pattern 210 is configured to have a sufficient width in the thickness direction of downwardly extending portion 180. Consequently, the solder bonding strength higher than that obtained by positioning land pattern 220 can be achieved.

It is to be noted that a push-pull gage (CPU Gage MODEL-RX-10, Push pull gage stand Model-1308 manufactured by Aikoh Engineering Co., Ltd.) was used for measuring the solder bonding strength. Also in the measurement, the pull strength was measured using an air reflow FPC substrate.

By providing fixing land pattern 210 that is greater in width in the thickness direction of downwardly extending portion 180 than positioning land pattern 220, the solder bonding strength is improved as compared with the case where only positioning land pattern 220 is provided.

Furthermore, the strength against peeling can be further improved by increasing the width of positioning land pattern 220. This is, however, not preferable since the shield case mounting portion is increased in size to cause a decrease in the positioning accuracy of shield case 170. It is preferable to establish the relation between thickness L1 of downwardly extending portion 180 of shield case 170 and width L2 of positioning land pattern 220 such that the ratio therebetween is 1<(L2/L1)≦5. This allows improvement in the positional accuracy.

According to the above-described configuration, the positioning accuracy of shield case 170 and the solder bonding strength of shield case 170 can both be ensured, which can be, in other words, achieved by ensuring the solder bonding strength by fixing land pattern 210 having a relatively broad width and also by ensuring the positioning accuracy by positioning land pattern 220 having a relatively narrow width. Furthermore, the mounting area can be reduced in size as compared with the case where all land patterns are increased in size.

Referring to FIGS. 8 to 12, the process of fixing shield case 170 to circuit substrate 200 will then be described. FIGS. 8 to 12 each are a perspective view showing each process of fixing the shield case to the circuit substrate according to the present embodiment.

FIG. 8 shows circuit substrate 200 on which electronic component mounting area 230 and land patterns 210 and 220 are formed. In the present embodiment, used as circuit substrate 200 is a flexible printed circuit substrate provided thereon with a wiring pattern made of copper foil and the like forming a circuit on the film.

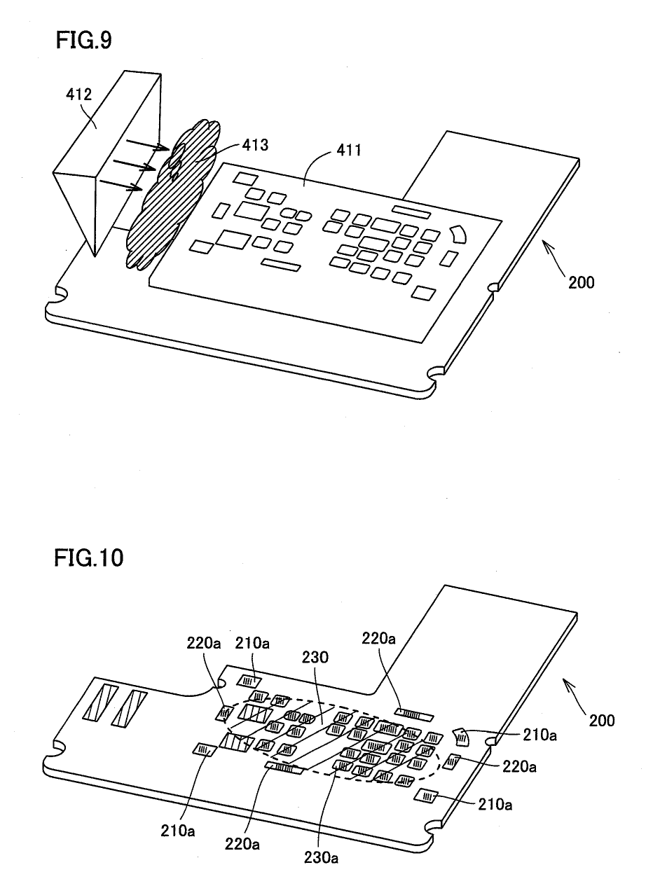

FIG. 9 shows a process of applying a solder paste 413 on circuit substrate 200. As shown in FIG. 9, solder paste 413 is applied by a printer 412 using an aperture mask 411. Aperture mask 411 is provided with an aperture in a position corresponding to each of the land patterns provided in electronic component mounting area 230 and land patterns 210 and 220 used for mounting the shield case, which are formed on circuit substrate 200.

Solder paste 213 is applied on each of the land patterns in electronic component mounting area 230 and land patterns 210 and 220, which results in the state as shown in FIG. 10.

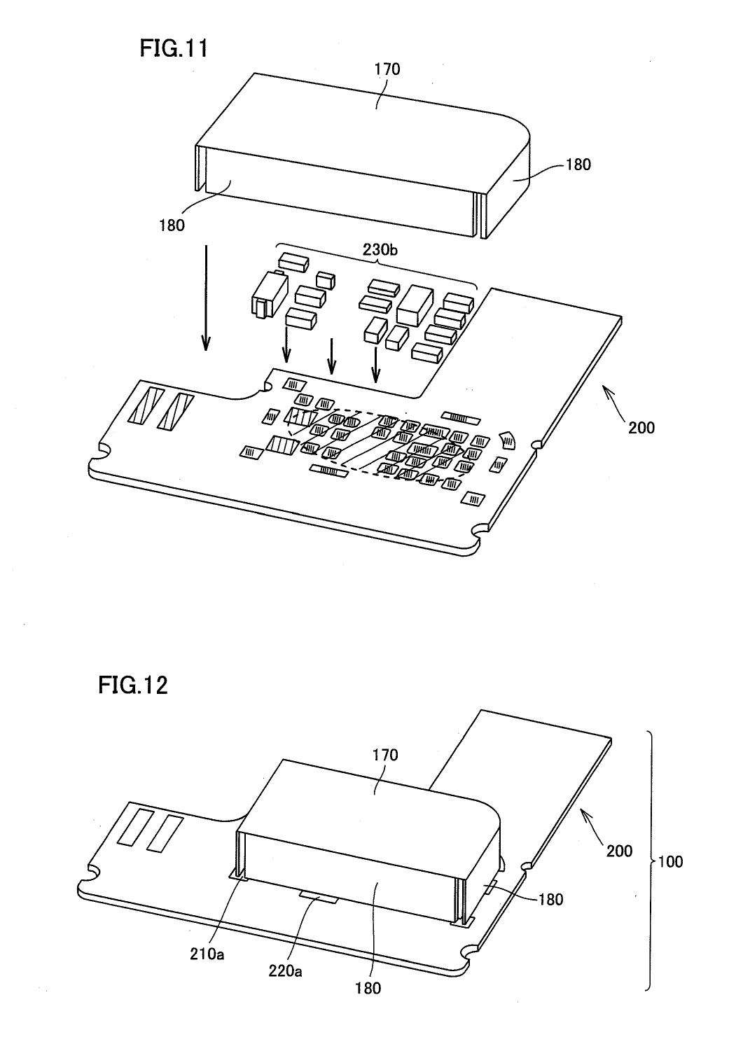

Then, as shown in FIG. 11, electronic components (a capacitor, a resistance, a coil, a diode, and the like) 230b are mounted on electronic component mounting area 230. Then, shield case 170 is mounted in the position corresponding to each of land patterns 210 and 220. In the present embodiment, electronic components 230b and shield case 170 are mounted on circuit substrate 200 using a mounting machine.

As shown in FIG. 12, electronic components 230b and shield case 170 mounted on circuit substrate 200 is then introduced into and passed through the high temperature bath to melt solder pastes 210a, 220a and 230a. Electronic components 230b are bonded to shield case 170 with melted solder pastes 210a, 220a and 230a to thereby form shield case mounting substrate 100 according to the present embodiment.

According to the method of manufacturing the shield case mounting substrate as described above, the land patterns used for mounting electronic components 230b, land pattern 210 used for fixing shield case 170 and land pattern 220 mainly used for positioning shield case 170 are provided on circuit substrate 200. Therefore, only one process is required for solder-bonding the electronic components, and positioning and fixing shield case 170. In other words, the number of processes of adhesion and the like for fixing shield case 170 is not increased. Shield case 170 can be positioned with high accuracy and fixed with high strength, both of which can be achieved with the fewest possible number of processes.

In the present embodiment, shield case 170 is configured to have a square shape in plan view, in which positioning land pattern 220 is provided in the position corresponding to each of its sides. In other words, positioning land patterns 220 are arranged so as to extend in the direction orthogonal to one another. Positioning land pattern 220 mainly limits movement of downwardly extending portion 180 in the thickness direction thereof. Accordingly, when a plurality of positioning land patterns 220 are provided so as to extend in the direction orthogonal to one another, shield case 170 having a rectangular shape in plan view can be positioned with accuracy.

Furthermore, in the present embodiment, the bonding strength of shield case 170 is ensured mainly by fixing land pattern 210, which eliminates the need of a mechanical fitting structure and the like. Consequently, as in the present embodiment, even when a flexible printed circuit substrate is used as circuit substrate 200, shield case 170 can be firmly fixed.

### Second Embodiment

The second embodiment according to the present invention will be hereinafter described with reference to the drawings.

The present embodiment is identical in basic configuration to the first embodiment, but mainly different in that notch portion 185 for improving the bonding strength is provided at the lower end of downwardly extending portion 180 of shield case 170 bonded to land patterns 210 and 220.

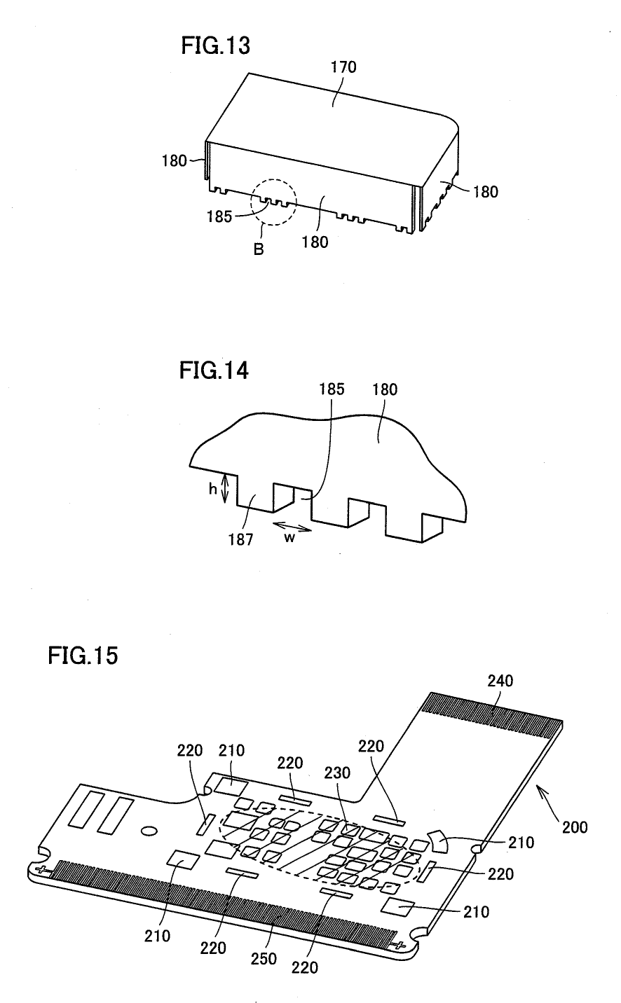

FIG. 13 is a perspective view showing the structure of the shield case according to the present embodiment. FIG. 14 is an enlarged view of a section B in FIG. 13.

As shown in FIGS. 13 and 14, notch portion 185 of a rectangular shape is provided at the lower end of downwardly extending portion 180 of shield case 170. When notch portion 185 is provided, downwardly extending portion 180 of shield case 170 is bonded to each of land patterns 210 and 220 via a rectangular piece 187 at the lower end of downwardly extending portion 180.

A plurality of notch portions 185 are provided in one downwardly extending portion 180. Specifically, as shown in FIG. 14, two notch portions 185 are provided in one downwardly extending portion 180 and bonded to land patterns 210 and 220 via three rectangular pieces 187.

By way of example only, in the present embodiment, notch portion 185 is configured to have a height H of 0.3 mm and a width W of 0.3 mm. The number, size and pitch of notch portion 185 can be variously changed as appropriate.

FIG. 15 is a perspective view showing the structure of the circuit substrate used in the present embodiment. In the present embodiment, two positioning land patterns 220 are provided in their respective positions corresponding to the longer sides of shield case 170. Positioning land pattern 220 is configured to have width L2 of 0.2 mm in the thickness direction of downwardly extending portion 180 (see FIG. 4). Positioning land pattern 220 is configured to have a longer side of 1.4 mm in length which is approximately equal to the length from one end to the other end of corresponding three rectangular pieces 187.

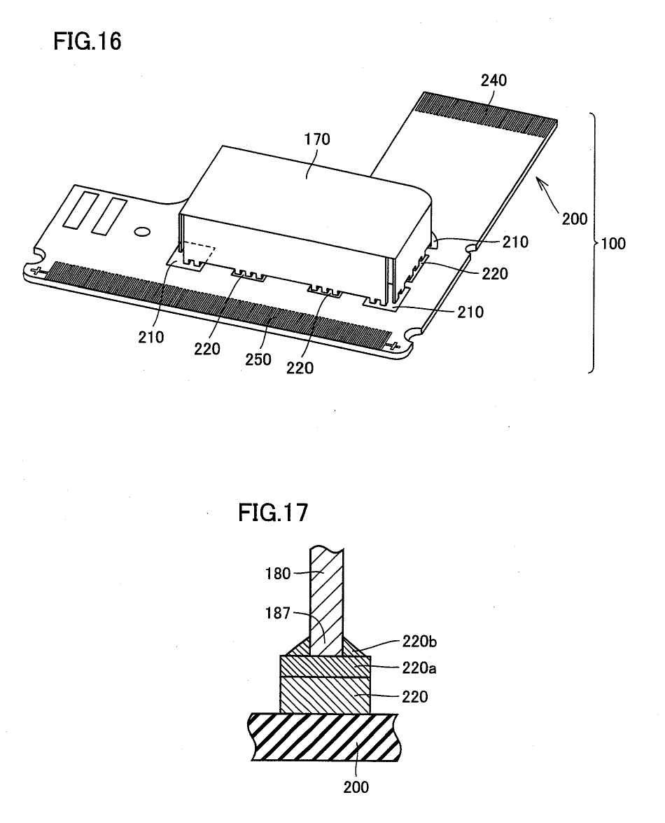

FIG. 16 is a perspective view showing the structure of the shield case mounting substrate according to the present embodiment. As shown in FIG. 16, in the state where shield case 170 is fixed on circuit substrate 200, each rectangular piece 187 at the lower end of downwardly extending portion 180 is located on the corresponding one of land patterns 210 and 220.

In the present embodiment, land pattern 220 used for positioning shield case 170 is configured to have a longer side having a length of 1.4 mm and a shorter side (L2) having a length of 0.2 mm. A total of six positioning land patterns 220 are provided so as to correspond to four sides of shield case 170. Since downwardly extending portion 180 has a thickness (L1) of 0.1 mm, the positioning error of shield case 170 falls within the range of ±0.05 mm in the vertical and lateral directions, which allows positioning with extremely high accuracy.

Then, the details of the bonding structure between shield case 170 and circuit substrate 200 according to the present embodiment will be described with reference to FIG. 17.

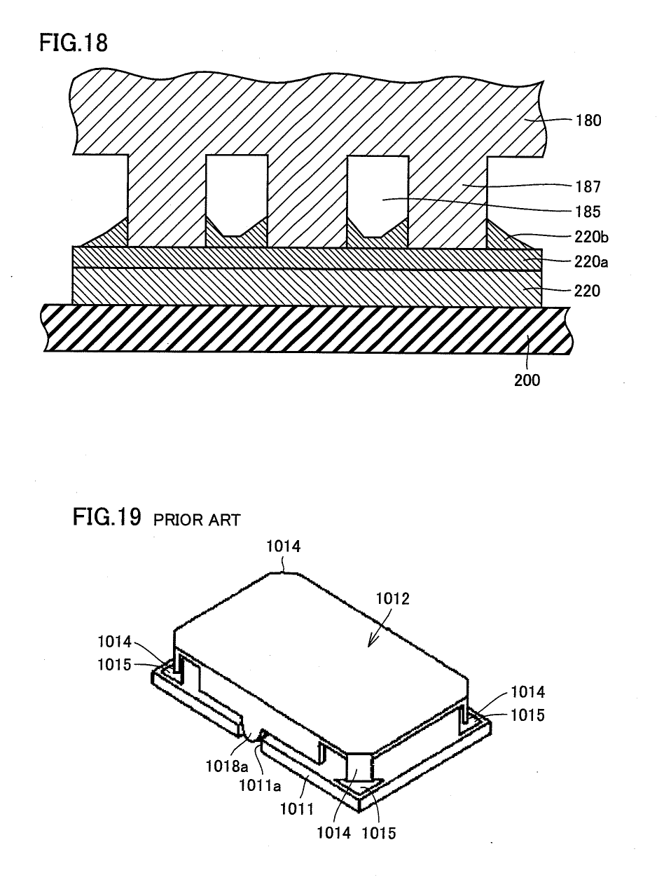

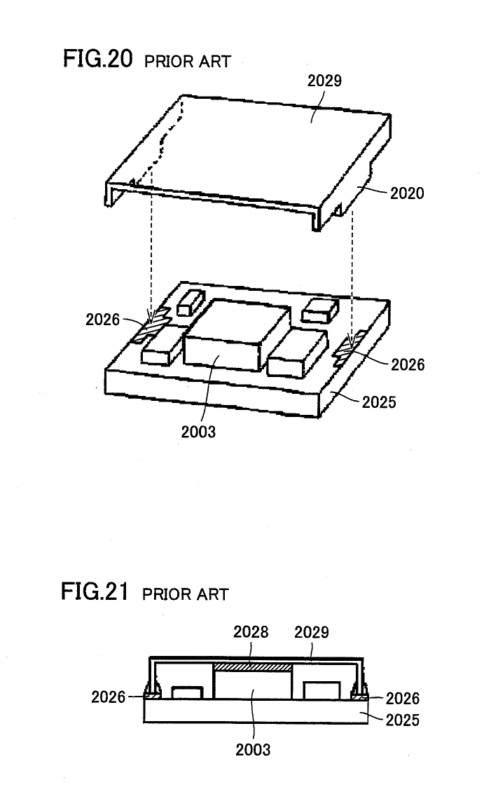

FIGS. 17 and 18 each are an enlarged cross-sectional view showing the structure of the connection portion of the shield case mounted on the circuit substrate.

When shield case 170 according to the present embodiment is solder-bonded in the process similar to that in the first embodiment, a solder fillet 220b is formed on the side of rectangular piece 187 of downwardly extending portion 180, as shown in FIG. 17.

As shown in FIG. 18, solder fillet 220b is formed also on each of the sides facing each other between a pair of rectangular pieces 187 and 187 adjacent thereto (the side surface on the notch portion 185 side). Furthermore, solder paste 220a having a sufficient thickness remains in the portion of land pattern 220 corresponding to notch portion 185.

Accordingly, the area of contact between the solder paste and land pattern 220 can be sufficiently ensured. Due to these effects, the bonding strength between downwardly extending portion 180 and land pattern 220 reaches 0.38 kgf for each part. Consequently, approximately 1.4 times of the bonding strength can be achieved as compared with the case where notch portion 185 is not provided.

It is to be noted that the shape of the notch portion is not limited to those in the present embodiments, but may be any shape that causes an increase in the bonding area between the solder and land pattern 220 and in the bonding area between the solder and downwardly extending portion 180.

It should be understood that the embodiments disclosed herein are illustrative and non-restrictive in every respect. The technical scope of the present invention is defined by the terms of the claims, rather, than only the description above, and is intended to include any modifications within the scope and meaning equivalent to the terms of the claims.

### INDUSTRIAL APPLICABILITY

According to the present invention, a shield case mounting substrate can be provided which is capable of ensuring the bonding strength between the metal case and the substrate and also capable of positioning the metal case with high accuracy.

### DESCRIPTION OF THE REFERENCE SIGNS

100 shield case mounting substrate, 170 shield case, 172 main body, 180 downwardly extending portion, 185 notch portion, 187 rectangular piece, 200 circuit substrate, 210 (fixing) land pattern, 220 (positioning) land pattern, 210a, 213, 220a, 230a solder paste, 210b, 220b solder fillet, 230 electronic component mounting area, 230b electronic component, 240 electronic equipment connection terminal, 250 liquid crystal display element connection terminal, 411 aperture mask, 412 printer, 413 solder paste.

1. A shield case mounting substrate comprising:
a substrate;
an electronic component mounted on said substrate;
a shield case made of metal having a main body covering said electronic component from above and a downwardly extending portion contiguous to an end of said main body and extending downwardly in a direction of said substrate;
a first land pattern provided on a surface of said substrate and to which a lower end of corresponding said downwardly extending portion is solder-bonded; and
a second land pattern provided on the surface of said substrate and to which a lower end of corresponding said downwardly extending portion is solder-bonded,
a width of said first land pattern in a thickness direction of said downwardly extending portion being greater than a width of said second land pattern in the thickness direction of said downwardly extending portion.

2. The shield case mounting substrate according to claim 1, wherein, when a thickness of said downwardly extending portion is L1 and the width of said second land pattern in the thickness direction of said downwardly extending portion is L2, L1 and L2 are set so as to satisfy a relation of 1<(L2/L1)≦5.

3. The shield case mounting substrate according to claim 1, wherein a plurality of said first land patterns and a plurality of said second land patterns are provided.

4. The shield case mounting substrate according to claim 1, wherein
an outer edge of said main body has four sides extending linearly,
said downwardly extending portion is formed to extend downwardly from an edge of each of said four sides,
at least four said second land patterns are provided, and
at least one of said second land patterns is provided in a position corresponding to each of said four sides.

5. The shield case mounting substrate according to claim 1, wherein the downwardly extending portion corresponding to said second land pattern has the lower end provided with a notch portion.

6. The shield case mounting substrate according to claim 1, wherein said substrate is a flexible printed circuit substrate.
